(19) United States
(12) Patent Application Publication
(10) Pub. No.: US 2026/0371958 A1
(43) Pub. Date: Nov. 19, 2026

(54) METHOD FOR FORMING SEMICONDUCTOR STRUCTURE, METHOD FOR OPTIMIZING PROFILE OF SILICON NITRIDE LAYER, AND SEMICONDUCTOR STRUCTURE

(71) Applicant: ASM IP Holding B.V., Almere (NL)

(72) Inventors: SeongRyeong Kim, Hwaseong-si (KR); JeungHoon Han, Yongin-si (KR); KiKang Kim, Yongin-si (KR); Jeonghoon Jang, Hwaseong-si (KR); YoungMin Kim, Hwaseong-Si (KR); Haein Kim, Hwaseong-Si (KR); Hyungjun Chee, Yongin-si (KR)

(21) Appl. No.: 19/675,773

(22) Filed: May 13, 2026

Related U.S. Application Data
(60) Provisional application No. 63/806,767, filed on May 16, 2025.

(51) Int. Cl. H10P 14/694; H10P 14/60; H10P 50/28; H10P 74/00; H10P 74/20

(52) U.S. Cl. CPC H10P 14/69433; H10P 14/6316; H10P 14/6319; H10P 14/6336; H10P 14/6534; H10P 14/6682; H10P 50/283; H10P 74/203; H10P 74/238

(57) ABSTRACT

A method for forming a semiconductor structure including a silicon nitride (SiN) layer is provided. The method includes performing a deposition process to deposit an amorphous silicon (a-Si) layer over a substrate including a gap and performing an etching process on the a-Si layer. The method also includes performing a nitridation process to convert at least a portion of the a-Si layer into a SiN layer and repeating the deposition process, the etching process, and the nitridation process until the target bottom thickness of the SiN layer within the gap is achieved.

### CROSS-REFERENCE TO RELATED APPLICATIONS

This application claims priority to U.S. Provisional Patent Application Ser. No. 63/806,767 filed May 16, 2025 titled METHOD FOR FORMING SEMICONDUCTOR STRUCTURE, METHOD FOR OPTIMIZING PROFILE OF SILICON NITRIDE LAYER, AND SEMICONDUCTOR STRUCTURE, the disclosure of which is hereby incorporated by reference in its entirety.

### BACKGROUND OF THE INVENTION

### Field of the Invention

The present disclosure relates to semiconductor processing, and more specifically it relates to the formation of silicon nitride (SiN) layers within gaps in a substrate.

### Background

Conventional deposition processes often face limitations in depositing sufficient thickness of SiN at the bottom of gaps in a substrate without causing unwanted sidewall deposition or overhang deposition. These shortcomings hinder effective device isolation, reliability, and protection.

### BRIEF SUMMARY OF THE INVENTION

A method for forming a semiconductor structure including a silicon nitride (SiN) layer is provided. The method includes performing a deposition process to deposit an amorphous silicon (a-Si) layer over a substrate including a gap and performing an etching process on the a-Si layer. The method also includes performing a nitridation process to convert at least a portion of the a-Si layer into a SiN layer and repeating the deposition process, the etching process, and the nitridation process until the target bottom thickness of the SiN layer within the gap is achieved.

In some embodiments, the target bottom thickness of the SiN layer within the gap is in a range between 150 Å to 300 Å. In some embodiments, the method further includes performing a post-etching process after the target bottom thickness of the SiN layer within the gap is achieved. In some embodiments, dilute hydrofluoric acid (DHF) or phosphoric acid (H₃PO₄) is used in the post-etching process to refine the profile of the SiN layer. In some embodiments, the post-etching process is performed until a sidewall width of the SiN layer within the gap is less than 30 Å. In some embodiments, the post-etching process is conducted at approximately 250 °C.

In some embodiments, the deposition process is performed using a CCP plasma generated using an RF frequency in the range of about 1 MHz to 100 MHz (such as 13.56 MHz) with a gas mixture including a silicon-containing gas selected from silane (SiH₄), disilane (Si₂H₆), hydrosilanes, silicon halides or organosilicon compounds, and one or more additional gases including hydrogen (H₂), helium (He), and argon (Ar). In some embodiments, the etching process is performed using a CCP plasma generated using an RF frequency in the range of about 1 MHz to 100 MHz (such as 13.56 MHz) with a gas mixture including hydrogen (H₂), helium (He), and argon (Ar). In some embodiments, the nitridation process is performed using a CCP plasma generated using an RF frequency in the range of about 1 MHz to 100 MHz (such as 13.56 MHz) with a gas mixture including nitrogen (N₂), ammonia (NH₃), hydrogen (H₂), and helium (He). In some embodiments, the etching process and the nitridation process are performed in the same reaction chamber.

A method for optimizing the profile of a silicon nitride (SiN) layer is provided. The method includes performing a plurality of cycles of a-Si deposition process, H₂ etching process, and nitridation process. The method also includes measuring the thickness of the resulting SiN layer after each cycle. The method further includes adjusting the process parameters to achieve the desired thickness of the SiN layer.

In some embodiments, the process parameters include deposition time, etching duration, and nitridation temperature. In some embodiments, the method further includes performing a DHF post-etching process or a H₃PO₄ post-etching process to further refine the profile of the SiN layer. In some embodiments, the measurement is conducted using a real-time thickness measurement system. In some embodiments, the profile of the SiN layer is monitored using transmission electron microscopy (TEM). In some embodiments, the cycle is repeated at least 10 times. In some embodiments, the cycle is repeated at least 20 times.

A semiconductor structure is provided. The semiconductor structure includes a silicon substrate and a bottom SiN film having the thickness greater than 150 Å and formed on the silicon substrate using a cyclic deposition-etching-nitridation process.

In some embodiments, the silicon substrate includes a plurality of gaps, and the bottom SiN film is formed within each of the gaps. In some embodiments, the semiconductor structure further includes a gate structure formed on the silicon substrate and adjacent to the bottom SiN film.

### BRIEF DESCRIPTION OF THE DRAWINGS

The present disclosure can be more fully understood by reading the detailed description and examples with references made to the accompanying drawings. It should be noted that various features may be not drawn to scale. In fact, the dimensions of the various features may be arbitrarily increased or decreased for clarity of discussion, and the various features may be drawn schematically.

FIG. 1A to FIG. 1G illustrate exemplary steps of a method for forming a silicon nitride (SiN) layer within a gap of a substrate, in accordance with some embodiments.

FIG. 2A illustrates the process flow of a deposition process, in accordance with some embodiments.

FIG. 2B illustrates the process flow of an etching process, in accordance with some embodiments.

FIG. 2C illustrates the process flow of a nitridation process, in accordance with some embodiments.

FIG. 3 illustrates a system in which the method may be performed, in accordance with some embodiments.

FIG. 4 illustrates a flow chart of a method for forming a semiconductor structure including a SiN layer, in accordance with some embodiments.

FIG. 5 illustrates a flow chart of a method for optimizing the profile of a SiN layer, in accordance with some embodiments.

### DETAILED DESCRIPTION OF THE INVENTION

The following description provides different embodiments, or examples, for implementing different features of the present disclosure. In addition, spatially relative terms may be used in the following description to describe the arrangements of various features. These spatially relative terms are for ease of describing the positional relationship between one feature and another feature as illustrated in the drawings. These spatially relative terms are intended to encompass different orientations of the device in use or operation in addition to the orientation illustrated in the drawings. The device may be otherwise oriented (rotated 90 degrees or at other orientations), and the spatially relative terms used in the following description may likewise be interpreted accordingly. For example, if a device of the drawings is flipped upside down, a feature that is “above” will become a feature that is “below”.

For example, the formation of a first feature “on,” “over,” or “under” a second feature in the following description may include embodiments in which the first and second features are formed in direct contact, and may also include embodiments in which additional features may be formed between the first feature and the second feature, such that the first feature and the second feature are not in direct contact.

In the following description, the terms “including”, “comprising”, “having”, and the like should be interpreted as meaning “including but not limited to . . . ”. Therefore, when the terms “including”, “comprising”, “having”, and the like are used, the presence of corresponding features, regions, steps, operations and/or elements is specified, and without excluding the presence of other features, regions, steps, operations and/or elements.

As used herein, the term “substrate” can refer to any underlying material or materials that may be used to form, or upon which, a device, a circuit, or a film may be formed. A substrate can include a bulk material, such as silicon (e.g., single-crystal silicon), other Group IV materials, such as germanium, or compound semiconductor materials, such as Group III-V or Group II-VI semiconductors, and can include one or more layers overlying or underlying the bulk material. Further, the substrate can include various features, such as gaps (e.g., recesses or vias), lines or protrusions, such as lines having gaps formed therebetween, and the like formed on or within at least a portion of a layer or bulk material of the substrate. By way of examples, one or more features can have an aspect ratio of about 1:1, 1:3, 1:10, 1:100, or more, or any ranges therebetween. In some examples, the one or more features may comprise a gap structure comprising a bottom and one or more sidewalls. In some examples, the one or more sidewalls may not be straight, such that the width of the gap structure is not uniform by the depth. In some examples, the one or more sidewalls may have a convex shape. In some examples, the one or more sidewalls may bulge below an opening of the gap structure. In some examples, the gap structure may have a neck at the opening of the gap structure.

As used herein, the term “film” refers to a layer extending in a direction perpendicular to a thickness direction. As used herein, the term “layer” refers to a material having a certain thickness formed on a surface and can be a synonym of a film or a non-film structure. A film or layer may be constituted by a discrete single film or layer having certain characteristics or multiple films or layers, and a boundary between adjacent films or layers may or may not be clear and may or may not be established based on physical, chemical, and/or any other characteristics, formation processes or sequence, and/or functions or purposes of the adjacent films or layers. The layer or film can be continuous—or not. Further, a single film or layer can be formed using one or more deposition cycles and/or one or more deposition and treatment cycles.

As used herein, the term “structure” can refer to a partially or completely fabricated device structure. By way of examples, a structure can be a substrate or include a substrate with one or more layers and/or features formed thereon.

As used herein, the term “chemical vapor deposition” (CVD) may refer to any process wherein a substrate is exposed to one or more volatile precursors, which react and/or decompose on a substrate surface to produce a desired deposition.

As used herein, the term “atomic layer deposition” (ALD) may refer to a vapor deposition process in which deposition cycles, preferably a plurality of consecutive deposition cycles, are conducted in a process chamber. Typically, during each cycle the precursor is chemisorbed to a deposition surface (e.g., a substrate surface or a previously deposited underlying surface such as material from a previous ALD cycle), forming a mono-layer or sub-monolayer that does not readily react with additional precursor (i.e., a self-limiting reaction). Thereafter, if necessary, a reactant (e.g., another precursor or reaction gas) may subsequently be introduced into the process chamber for use in converting the chemisorbed precursor to the desired material on the deposition surface. Typically, this reactant is capable of further reaction with the precursor. Further, purging steps may also be utilized during each cycle to remove excess precursor from the process chamber and/or remove excess reactant and/or reaction byproducts from the process chamber after conversion of the chemisorbed precursor. Further, the term atomic layer deposition, as used herein, is also meant to include processes designated by related terms such as, chemical vapor atomic layer deposition, atomic layer epitaxy (ALE), molecular beam epitaxy (MBE), gas source MBE, or organometallic MBE, and chemical beam epitaxy when performed with alternating pulses of precursor composition(s), reactive gas, and purge (e.g., inert carrier) gas.

As used herein, the term “cyclic deposition process” can refer to a vapor deposition process in which deposition cycles, typically a plurality of consecutive deposition cycles, are conducted in a process chamber. Cyclic deposition processes can include cyclic plasma-enhanced CVD, ALD, and/or plasma-enhanced ALD (PEALD) processes. A cyclic deposition process can include one or more cycles that include plasma activation of a precursor, a reactant, and/or an inert gas in any combination.

As used herein, the term “continuously” can refer to without breaking a vacuum, without interruption as a timeline, without any material intervening step, without changing treatment conditions, immediately thereafter, as a next step, or without an intervening discrete physical or chemical structure between two structures other than the two structures in some embodiments and depending on the context.

In this disclosure, any two numbers of a variable can constitute a workable range of the variable, and any ranges indicated may include or exclude the endpoints. Additionally, any values of variables indicated (regardless of whether they are indicated with “about” or not) may refer to precise values or approximate values and include equivalents, and may refer to average, median, representative, majority, etc. in some embodiments.

Where an (e.g., RF) plasma is used, a low RF frequency (LF) may be lower than 1 MHz, or between 430 kHz and 1 MHz, or between about 40 kHz and 800 kHz, a high RF frequency (HF) may be greater than 1 MHz, or between 13 and 100 MHz, or between about 13.56 MHz and 27 MHz, and a very high RF frequency (VHF) may be greater than 27 MHz, greater than 30 MHz, greater than 40 MHz, greater than 60 MHz, or between about 30 MHz and 5 GHz.

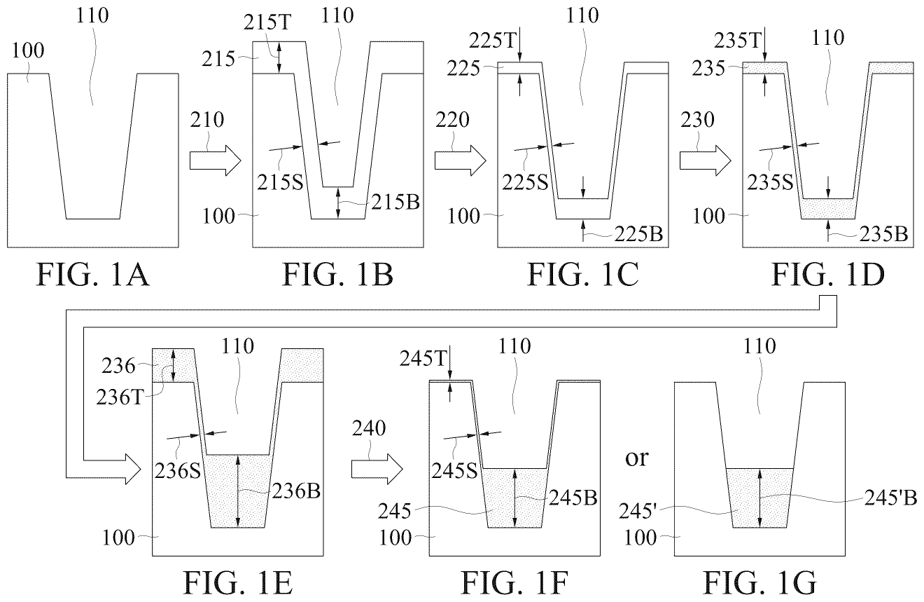

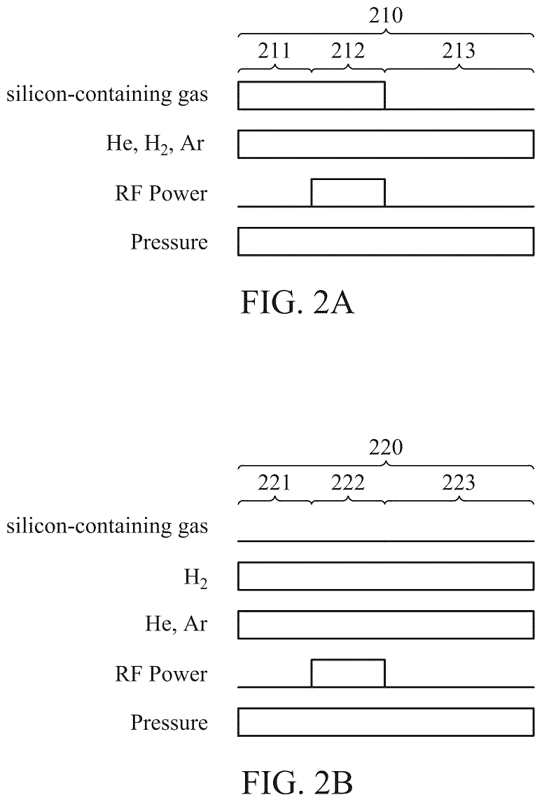

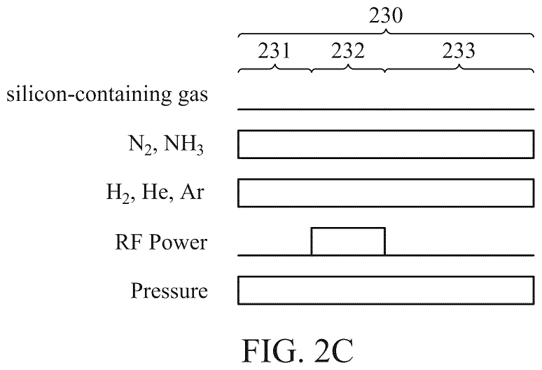

Please refer to FIG. 1A to FIG. 1G and FIG. 2A to FIG. 2C. FIG. 1A to FIG. 1G illustrate exemplary steps of a method for forming a silicon nitride (SiN) layer (e.g., 235, 236, 245, or 245′) within a gap 110 of a substrate 100, in accordance with some embodiments. The substrate 100 may be a wafer, such as a silicon wafer. Other substrates, such as a multi-layered or gradient substrate may also be used. In some embodiments, the semiconductor material of the substrate 100 may include silicon; germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof. The gap 110 may be a trench or via in the substrate 100.

The method includes a deposition process 210, an etching process 220, and a nitridation process 230, and an optional post-etching process 240. FIG. 2A illustrates the process flow of the deposition process 210, in accordance with some embodiments. FIG. 2B illustrates the process flow the etching process 220, in accordance with some embodiments. FIG. 2C illustrates the process flow of the nitridation process 230, in accordance with some embodiments.

The deposition process 210 may also be referred to as an a-Si deposition process, as it forms an amorphous silicon (a-Si) layer 215. In some embodiments, the deposition process 210 is performed using a CCP plasma generated using an RF frequency in the range of about 1 MHz to 100 MHz (such as 13.56 MHz) with a gas mixture including a silicon-containing gas selected from silane (SiH₄), disilane (Si₂H₆), hydrosilanes, silicon halides or organosilicon compounds, and one or more additional gases including hydrogen (H₂), helium (He), and argon (Ar). Specifically, the deposition process 210 may include a plurality of stages, including a feed stage 211, an RF-ON stage 212, and a post purge stage 213. In some embodiments, the deposition process 210 is performed for a duration ranging from about 10 seconds to 120 seconds. In some embodiments, the deposition process 210 is performed for less than 60 seconds. In some embodiments, the deposition process 210 is performed for approximately 10 seconds, 20 seconds, or 30 seconds.

The silicon-containing gas (such as SiH₄) is introduced at the start of the feed stage 211 with continuous flow through the RF-ON stage 212, and stops at the beginning of the post purge stage 213. Various gases, He, H₂, and Ar, are supplied continuously through-out all three stages (i.e., the feed stage 211, the RF-ON stage 212, and the post purge stage 213). RF power is off during the feed stage 211. RF power is turned on during the RF-ON stage 212, and it is turned off again at the start of the post purge stage 213. The pressure remains constant throughout the entire deposition process 210. In other words, the deposition process 210 begins with the silicon-containing gas and various gases flow, and RF Power is applied only during the middle phase (i.e., the RF-ON stage 212) to activate deposition. The post purge stage 213 continues with gas flow only to remove residual gases. The pressure is maintained steadily across all phases.

The formed a-Si layer 215 includes a top thickness 215T over the top sur-face of the substrate 100, a sidewall width 215S lining the sidewalls of the gap 110, and a bottom thickness 215B at the bottom of the gap 110. In some embodiments, the top thickness 215T of the a-Si layer 215 is greater than 150 Å. In some embodiments, the sidewall width 215S of the a-Si layer 215 is greater than 35 Å. In some embodiments, the bottom thickness 215B of the a-Si layer 215 is greater than 50 Å.

Next, the etching process 220 is performed. The etching process 220 may be a wet etching process. The etching process 220 may also be referred to as a H₂ etching process, as hydrogen plasma is required. The etching process 220 etches the a-Si layer 215 to form an etched a-Si layer 225. In some embodiments, the etching process 220 is performed using a CCP plasma generated using an RF frequency in the range of about 1 MHz to 100 MHz (such as 13.56 MHz) with a gas mixture including hydrogen (H₂), helium (He), and argon (Ar). Specifically, the etching process 220 may include a plurality of stages, including a feed stage 221, an RF-ON stage 222, and a post purge stage 223. In some embodiments, the etching process 220 is conducted for more than 50 seconds. In some embodiments, the etching process 220 is conducted for about 60 seconds to 110 seconds. In some embodiments, the etching process 220 is conducted for approximately 100 seconds.

H₂ is supplied continuously from the feed stage 221 through the post purge stage 223. Similar to the supply of H₂, He, and Ar (inert or carrier gases) are also continuously provided throughout all three stages (i.e., the feed stage 221, the RF-ON stage 222, and the post purge stage 223), helping to stabilize plasma and assisting in purging. RF power is off during the feed stage 221 and the post purge stage 223. RF power is turned on only during the RF-ON stage 222. RF power activates plasma. The pressure is maintained constant across all three stages (i.e., the feed stage 221, the RF-ON stage 222, and the post purge stage 223), providing a steady environment.

The etched a-Si layer 225 includes a top thickness 225T over the top surface of the substrate 100, a sidewall width 225S lining the sidewalls of the gap 110, and a bottom thickness 225B at the bottom of the gap 110. The top thickness 225T of the etched a-Si layer 225 is less than the top thickness 215T of the a-Si layer 215, the sidewall width 225S of the etched a-Si layer 225 is less than the sidewall width 215S of the a-Si layer 215, and the bottom thickness 225B of the etched a-Si layer 225 is less than or equal to the bottom thickness 215B of the a-Si layer 215, as the etching process 220 removes at least a portion of the a-Si layer 215.

In addition, the etching process 220 primarily etches the top area of the a-Si layer 215. Therefore, in some embodiments, the difference between the top thickness 225T of the etched a-Si layer 225 and the top thickness 215T of the a-Si layer 215 is greater than the difference between the bottom thickness 225B of the etched a-Si layer 225 and the bottom thickness 215B of the a-Si layer 215. In some embodiments, the difference between the sidewall width 225S of the etched a-Si layer 225 and the sidewall width 215S of the a-Si layer 215 may also be greater than the difference between the bottom thickness 225B of the etched a-Si layer 225 and the bottom thickness 215B of the a-Si layer 215.

Next, the nitridation process 230 is performed. The nitridation process 230 converts at least a portion of the etched a-Si layer 225 into a SiN layer 235. In some embodiments, the nitridation process 230 is performed using a CCP plasma generated using an RF frequency in the range of about 1 MHz to 100 MHz (such as 13.56 MHz) with a gas mixture including nitrogen (N₂), ammonia (NH₃), hydrogen (H₂), and helium (He). Specifically, the nitridation process 230 may include a plurality of stages, including a feed stage 231, an RF-ON stage 232, and a post purge stage 233. In some embodiments, the nitridation process 230 is performed for a duration ranging from about 10 seconds to 400 seconds. In some embodiments, the nitridation process 230 is performed for less than 200 seconds. In some embodiments, the nitridation process 230 is performed for approximately 50 seconds, 100 seconds, or 150 seconds. In some embodiments, the nitridation process 230 is conducted at a temperature between 100 °C and 600 °C. In some embodiments, the nitridation process 230 is conducted at approximately 400 °C.

Nitrogen reactants (for nitridation) such as N₂ and NH₃ are supplied continuously from the feed stage 231 through the post purge stage 233. Similar to the supply of the nitrogen reactants, H₂, He, and Ar (carrier gases) are also continuously provided throughout all three stages (i.e., the feed stage 231, the RF-ON stage 232, and the post purge stage 233), helping to stabilize plasma and assisting in purging. RF power is off during the feed stage 231 and the post purge stage 233. RF power is turned on only during the RF-ON stage 232. RF power activates plasma to initiate the nitridation reactions. The pressure is maintained constant throughout all three stages (i.e., the feed stage 231, the RF-ON stage 232, and the post purge stage 233), providing a steady environment.

The SiN layer 235 includes a top thickness 235T over the top surface of the substrate 100, a sidewall width 235S lining the sidewalls of the gap 110, and a bottom thickness 235B at the bottom of the gap 110. The top thickness 235T of the SiN layer 235, the sidewall width 235S of the SiN layer 235, and the bottom thickness 235B of the SiN layer 235 is greater than or equal to the top thickness 225T of the etched a-Si layer 225, the sidewall width 225S of the etched a-Si layer 225, and the bottom thickness 225B of the etched a-Si layer 225, respectively, as the nitridation process 230 converts a-Si into SiN.

In some embodiments, the deposition process 210, the etching process 220, and the nitridation process 230 are repeated for a number of cycles (e.g., 5-30) until a SiN layer 236 having a bottom thickness 236B greater than a target bottom thickness is formed, as shown in FIG. 1E. The SiN layer 236 also includes a top thickness 236T over the top sur-face of the substrate 100 and a sidewall width 236S lining the sidewalls of the gap 110. The top thickness 236T of the SiN layer 236, the sidewall width 236S of the SiN layer 236, and the bottom thickness 236B of the SiN layer 236 is greater than or equal to the top thickness 235T of the SiN layer 235, the sidewall width 235S of the SiN layer 235, and the bottom thickness 235B of the SiN layer 235, respectively.

In some embodiments, the target bottom thickness of the SiN layer 236 within the gap 110 is greater than 150 Å. That is, the deposition process 210, the etching process 220, and the nitridation process 230 are performed until the bottom thickness 236B of the SiN layer 236 exceeds 150 Å. In some embodiments, the target bottom thickness of the SiN layer 236 within the gap 110 is greater than 100 Å. That is, the deposition process 210, the etching process 220, and the nitridation process 230 are performed until the bottom thickness 236B of the SiN layer 236 exceeds 100 Å. In some embodiments, the target bottom thickness of the SiN layer 236 within the gap 110 is in a range between 150 Å to 300 Å.

A relatively thick bottom SiN layer can be particularly advantageous for electrostatic discharge (ESD) protection, field oxide etch barriers, and other dielectric applications requiring protection at the bottom of narrow features (e.g., gaps of a substrate). For example, in some embodiments, the SiN layer 236 may serve as a protective structure in ESD protection schemes or as a barrier during field oxide etch processes. The combination of deposition, selective etching, and nitridation enables formation of a bottom-thickened SiN profile.

In some embodiments, the cycle is repeated at least 10 times. In some embodiments, the cycle is repeated at least 20 times. The number of cycles may depend on desired target bottom thickness (e.g., 100 Å, 150 Å, or 150 Å to 300 Å) of the SiN layer 236 within the gap 110, a-Si deposition rate during the deposition process 210, etching rate during the etching process 220, and conversion efficiency during the nitridation process 230. This cyclic approach allows for precise control over the SiN deposition profile, particularly in achieving a relatively thick bottom portion of the SiN layer while minimizing excessive deposition on the top and sidewall regions.

It should be noted that the thickness of the resulting SiN layer (e.g., the sidewall width 235S of the SiN layer 235 and/or the bottom thickness 235B of the SiN layer 235) may be measured after each cycle, and the process parameters can be adjusted accordingly to better achieve the desired thickness of the SiN layer. The process parameters include temperature, pressure, a-Si deposition rate, deposition time, etching duration, cycle repetition, plasma parameters, chamber conditions, and the like. In some embodiments, the measurement is conducted using a real-time thickness measurement system. In some embodiments, the profile of the SiN layer is monitored using transmission electron microscopy (TEM).

By measuring the SiN layer thickness (e.g., the sidewall width 235S of the SiN layer 235 and/or the bottom thickness 235B of the SiN layer 235) after each cycle, the process enables precise control over the film growth. In addition, adjusting the process parameters such as temperature, pressure, deposition rate, and etching duration in real-time allows dynamic tuning of the process for optimal results. Furthermore, real-time monitoring and parameter adjustments contribute to consistent layer formation across cycles, improving process repeatability and film uniformity and leading to more reliable and predictable yields.

A resulting semiconductor structure is provided. The semiconductor structure includes a silicon substrate (such as a substrate 100) and a bottom SiN film (such as the bottom region of the SiN layer 236) having the thickness greater than 150 Å and formed on the silicon substrate using a cyclic deposition-etching-nitridation process. In some embodiments, the silicon substrate includes a plurality of gaps, and the bottom SiN film is formed within each of the gaps. In some embodiments, the semiconductor structure may further include a gate structure formed on the silicon substrate and adjacent to the bottom SiN film.

In some embodiments, after the target bottom thickness of the SiN layer 236 within the gap 110 is achieved, a post-etching process 240 may be performed, thereby forming a SiN layer (245 in FIG. 1F or 245′ in FIG. 1G). The post-etching process 240 may refine the profile of the SiN layer 236. The post-etching process 240 may be a wet etching process. In some embodiments, the post-etching process 240 may be referred to as a DHF post-etching process, as DHF is used in the post-etching process 240. In some embodiments, a 200:1 DHF solution is used. In some embodiments, the post-etching process 240 may be referred to as a H₃PO₄ post-etching process, as H₃PO₄ is used in the post-etching process 240. In some embodiments, a H₃PO₄ solution having a concentration of approximately 85% is used. In some embodiments, the post-etching process 240 is conducted for more than 50 seconds. In some embodiments, the post-etching process 240 is conducted for about 100 seconds to 300 seconds. In some embodiments, the post-etching process 240 is conducted for approximately 100 seconds, approximately 150 seconds, or approximately 200 seconds. In some embodiments, the post-etching process 240 is conducted at a temperature between 100 °C and 500 °C. In some embodiments, the post-etching process 240 is conducted at approximately 250 °C.

As shown in FIG. 1F, the SiN layer 245 includes a top thickness 245T over the top surface of the substrate 100, a sidewall width 245S lining the sidewalls of the gap 110, and a bottom thickness 245B at the bottom of the gap 110. The top thickness 245T is less than the top thickness 236T of the SiN layer 236, the sidewall width 245S is less than the sidewall width 236S of the SiN layer 236, and the bottom thickness 245B is less than or equal to the bottom thickness 236B of the SiN layer 236, as the post-etching process 240 removes at least a portion of the SiN layer 236. In some embodiments, after the post-etching process 240 is performed, the bottom thickness 245B of the SiN layer 245 within the gap 110 is still greater than the target bottom thickness. In some embodiments, after the post-etching process 240 is performed, the bottom thickness 245B of the SiN layer 245 remains greater than 150 Å. In some embodiments, after the post-etching process 240 is performed, the bottom thickness 245B of the SiN layer 245 is greater than 100 Å.

In addition, the post-etching process 240 primarily etches the top area and/or the sidewall area of the SiN layer 236. Therefore, in some embodiments, the difference between the top thickness 245T of the SiN layer 245 and the top thickness 236T of the SiN layer 236 is greater than the difference between the bottom thickness 245B of the SiN layer 245 and the bottom thickness 236B of the SiN layer 236. In some embodiments, the difference between the sidewall width 245S of the SiN layer 245 and the sidewall width 236S of the SiN layer 236 may also be greater than the difference between the bottom thickness 245B of the SiN layer 245 and the bottom thickness 236B of the SiN layer 236.

In some embodiments, the post-etching process 240 is performed until the top thickness 245T of the SiN layer 245 over the top surface of the substrate 100 is reduced to less than 100 Å. In some embodiments, the post-etching process 240 is performed until the top thickness 245T of the SiN layer 245 over the top surface of the substrate 100 is reduced to approximately 30 Å. In some embodiments, the post-etching process 240 is performed until the sidewall width 245S of the SiN layer 245 within the gap 110 is reduced to less than 30 Å. In some embodiments, the post-etching process 240 is performed until the sidewall width 245S of the SiN layer 245 within the gap 110 is reduced to approximately 20 Å.

In some embodiments, the post-etching process 240 is performed until the SiN layer 245′ is selectively formed at the bottom of the gap 110 without forming any substantial thickness on the top surface of the substrate 100 or along the sidewalls of the gap 110, as shown in FIG. 1G.

The SiN layer 245′ includes a bottom thickness 245′B at the bottom of the gap 110. The bottom thickness 245′B is less than or equal to the bottom thickness 236B of the SiN layer 236. In some embodiments, after the post-etching process 240 is performed, the bottom thickness 245′B of the SiN layer 245′ within the gap 110 is still greater than the target bottom thickness. In some embodiments, after the post-etching process 240 is performed, the bottom thickness 245′B of the SiN layer 245′ remains greater than 150 Å. In some embodiments, after the post-etching process 240 is performed, the bottom thickness 245′B of the SiN layer 245′ is greater than 100 Å.

The deposition process 210, the etching process 220, the nitridation process 230, and the post-etching process 240 may be repeated for a number of cycles (e.g., 5-30). Alternatively, the post-etching process 240 may be performed only once after several cycles of the deposition process 210, the etching process 220, and the nitridation process 230 have been completed. In such a case, the deposition process 210, the etching process 220, and the nitridation process 230 are performed repeatedly, followed by a single post-etching process 240.

In some embodiments, all the processes (i.e., the deposition process 210, the etching process 220, the nitridation process 230, and the post-etching process 240) are performed in-situ without exposing the substrate 100 to air. That is, all the processes (i.e., the deposition process 210, the etching process 220, the nitridation process 230, and the post-etching process 240) are performed in the same reaction chamber. In some embodiments, the deposition process 210 and the etching process 220 are performed in the same reaction chamber. In some embodiments, the etching process 220 and the nitridation process 230 are performed in the same reaction chamber.

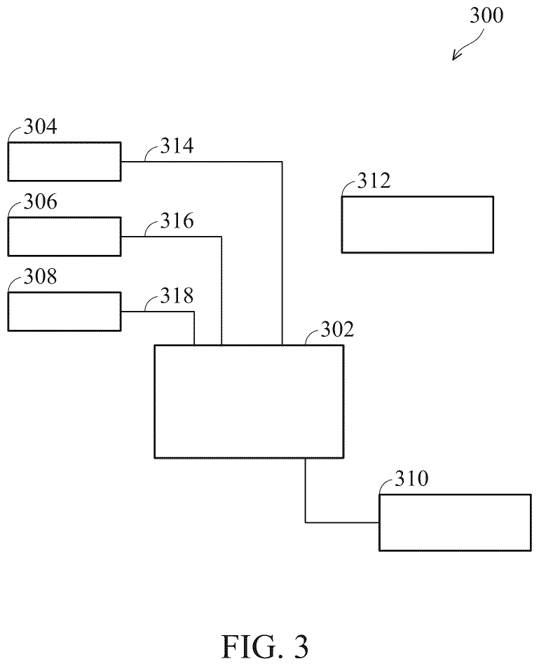

Next, please refer to FIG. 3. FIG. 3 illustrates a system 300 in which the method may be performed, in accordance with some embodiments. The system 300 can be used to perform a method as described herein and/or form a semiconductor structure as described herein.

In the illustrated example, the system 300 includes one or more reaction chambers 302, a precursor gas source 304, a nitrogen reactant gas source 306, a purge gas source 308, an exhaust source 310, and a controller 312. The reaction chamber 302 can include any suitable reaction chamber, such as a CVD chamber, an ALD chamber, or a PEALD reaction chamber. Although illustrated with one single reaction chamber 302, the system 300 can include any suitable number of reaction chamber, such as a first reaction chamber configured to deposit an a-Si layer, a second reaction chamber configured to perform an etching process on the a-Si layer, and a third reaction chamber configured to perform a nitridation process to convert at least a portion of the a-Si layer into a SiN layer. The first reaction chamber, the second reaction chamber, and the third reaction chamber may be capable of high vacuum isolation and wafer transfer automation.

The precursor gas source 304 can include a vessel and one or more precursors as described herein-alone or mixed with one or more carrier (e.g., inert) gases. The nitrogen reactant gas source 306 can include a vessel and one or more nitrogen reactants as described herein-alone or mixed with one or more carrier gases. The purge gas source 308 can include one or more inert gases as described herein. Although illustrated with three gas sources 304, 306, and 308, the system 300 can include any suitable number of gas sources. The gas sources 304, 306, and 308 can be coupled to the reaction chamber 302 via lines 314, 316, and 318, which can each include flow controllers, valves, heaters, and the like. The exhaust source 310 can include one or more vacuum pumps.

The controller 312 includes electronic circuitry and software to selectively operate valves, manifolds, heaters, pumps and other components included in the system 300. Such circuitry and components operate to introduce precursors, reactants, and purge gases from the respective sources 304, 306, and 308. The controller 312 can control timing of gas pulse sequences, temperature of the substrate and/or reaction chamber, pressure within the reaction chamber, and various other operations to provide proper operation of the system 300. The controller 312 can include control software to electrically or pneumatically control valves to control flow of precursors, reactants and purge gases into and out of the reaction chamber 302. The controller 312 can include modules such as a software or hardware component to perform certain tasks. A module can advantageously be configured to reside on the addressable storage medium of the control system and be configured to execute one or more processes.

Other configurations for the method to performed in are possible, including different numbers and kinds of precursor and reactant sources and purge gas sources. Further, it will be appreciated that there are many arrangements of valves, conduits, precursor sources, and purge gas sources that may be used to accomplish the goal of selectively feeding gases into reaction chamber 302. Further, as a schematic representation of a system, many components have been omitted for simplicity of illustration, and such components may include, for example, various valves, manifolds, purifiers, heaters, containers, vents, and/or bypasses. For example, an RF power source able to operate at 13.56 MHz may be coupled to the reaction chamber 302.

During operation of the system 300, substrates (e.g., the substrate 100) are transferred from, e.g., a substrate handling system to reaction chamber 302. Once substrate(s) are transferred to reaction chamber 302, one or more gases from gas sources 304, 306, and 308, such as precursors, reactants, carrier gases, and/or purge gases, are introduced into the reaction chamber 302.

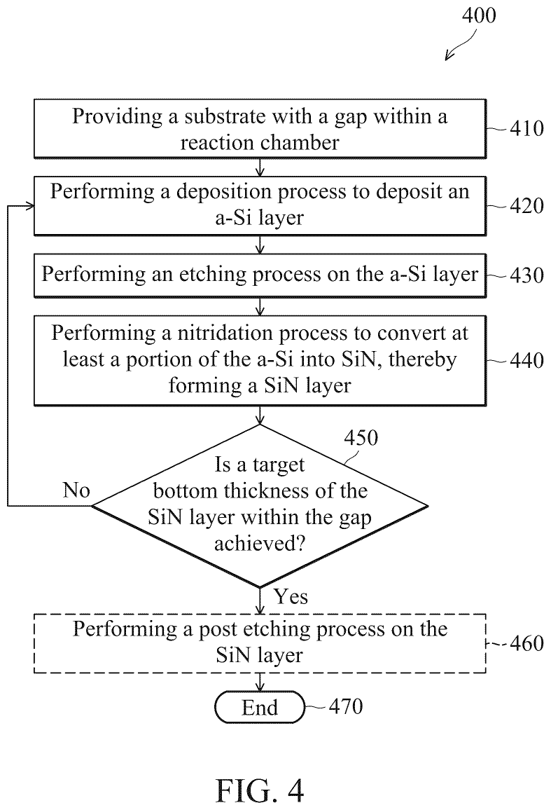

Next, please refer to FIG. 4. FIG. 4 illustrates a flow chart of a method 400 for forming a semiconductor structure including a SiN layer, in accordance with some embodiments. The method 400 includes a plurality of operations 410-470. In the operation 410, a substrate with a gap is provided within a reaction chamber. In the operation 420, a deposition process (e.g., the deposition process 210) is performed to deposit an a-Si layer. In the operation 430, an etching process (e.g., the etching process 220) is performed on the a-Si layer. In the operation 440, a nitridation process (e.g., the nitridation process 230) is performed to convert at least a portion of the a-Si layer into a SiN layer. In the operation 450, if the target bottom thickness of the SiN layer within the gap is achieved, the method 400 proceeds to the operation 460, where a post-etching process (e.g., the post-etching process 240) on the SiN layer is performed. Alternatively, if the target bottom thickness of the SiN layer within the gap is achieved, the method 400 may be terminated (the operation 470). If the target bottom thickness of the SiN layer within the gap is not achieved, the method 400 returns to the operation 420.

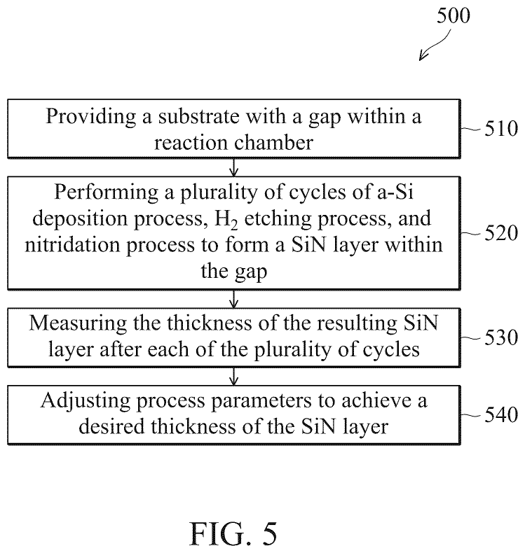

Next, please refer to FIG. 5. FIG. 5 illustrates a flow chart of a method 500 for optimizing the profile of a SiN layer, in accordance with some embodiments. The method 500 includes a plurality of operations 510-540. In the operation 510, a substrate with a gap is provided within a reaction chamber. In the operation 520, a plurality of cycles of a-Si deposition process, H₂ etching process, and nitridation process is performed to form a SiN layer within the gap. In some embodiments, the number of cycles is between 5 times to 30 times. In the operation 530, the thickness of the resulting SiN layer is measured after each of cycle. In some embodiments, the measurement is conducted using a real-time thickness measurement system. In the operation 540, based on the measurement results, the process parameters are adjusted to achieve the desired thickness of the SiN layer. In some embodiments, process parameters include temperature, pressure, a-Si deposition rate, deposition time, etching duration, cycle repetition, plasma parameters, chamber conditions, and the like.

To sum up, a method for forming a semiconductor structure including a SiN layer within a gap of a substrate is provided. The method includes cyclically depositing a-Si, etching the a-Si with hydrogen plasma (primarily thinning the top and sidewall regions while preserving the bottom), and converting the a-Si to SiN via nitridation. The method can further include an optional post-etching process to refine the SiN layer, selectively thinning the top and sidewalls while maintaining the bottom thickness. The deposition-etching-nitridation cycle is repeated multiple times (e.g., 5-30 cycles) to gradually build up the bottom thickness of the SiN layer. This allows formation of a SiN layer with the target bottom thickness greater than 100 Å or 150 Å, and in some embodiments, up to 300 Å or more.

The cyclic processes enable the formation of a thick bottom SiN layer, which can be particularly advantageous for electrostatic discharge (ESD) protection, field oxide etch barriers, and other dielectric applications requiring robust protection at the bottom of narrow features (e.g., substrate gaps). The number of cycles and process parameters can be tailored to meet requirements. In some embodiments, a real-time thickness measurement system is used to monitor film growth, enhancing process reliability and predictability. Furthermore, all processes can be performed in situ without exposing the substrate to air, thereby minimizing contamination.

The foregoing outlines features of several embodiments, so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced in the following description. Those skilled in the art should also realize that such equivalent constructions do not depart from the spirit and scope of the present disclosure, and that they may make various changes, substitutions, and alterations in the following description without departing from the spirit and scope of the present disclosure.

What is claimed is:

1. A method for forming a semiconductor structure comprising a silicon nitride (SiN) layer, the method comprising:
performing a deposition process to deposit an amorphous silicon (a-Si) layer over a substrate comprising a gap;
performing an etching process on the a-Si layer;
performing a nitridation process to convert at least a portion of the a-Si layer into a SiN layer; and
repeating the deposition process, the etching process, and the nitridation process until a target bottom thickness of the SiN layer within the gap is achieved.

2. The method of claim 1, wherein the target bottom thickness of the SiN layer within the gap is in a range between 150 Å to 300 Å.

3. The method of claim 1, further comprising performing a post-etching process after the target bottom thickness of the SiN layer within the gap is achieved.

4. The method of claim 3, wherein dilute hydrofluoric acid (DHF) or phosphoric acid (H₃PO₄) is used in the post-etching process to refine profile of the SiN layer.

5. The method of claim 3, wherein the post-etching process is performed until a sidewall width of the SiN layer within the gap is less than 30 Å.

6. The method of claim 3, wherein the post-etching process is conducted at approximately 250 °C.

7. The method of claim 1, wherein the deposition process is performed using a CCP plasma generated using an RF frequency in the range of about 1 MHz to 100 MHz with a gas mixture comprising a silicon-containing gas selected from silane (SiH₄), disilane (Si₂H₆), hydrosilanes, silicon halides or organosilicon compounds, and one or more additional gases including hydrogen (H₂), helium (He), and argon (Ar).

8. The method of claim 1, wherein the etching process is performed using a CCP plasma generated using an RF frequency in the range of 1 MHz to 100 MHz with a gas mixture comprising hydrogen (H₂), helium (He), and argon (Ar).

9. The method of claim 1, wherein the nitridation process is performed using a CCP plasma generated using an RF frequency in the range of 1 MHz to 100 MHz with a gas mixture comprising nitrogen (N₂), ammonia (NH₃), hydrogen (H₂), and helium (He).

10. The method of claim 1, wherein the etching process and the nitridation process are performed in the same reaction chamber.

11. A method for optimizing profile of a silicon nitride (SiN) layer, the method comprising:
performing a plurality of cycles of a-Si deposition process, H₂ etching process, and nitridation process;
measuring thickness of the resulting SiN layer after each of the plurality of cycles; and
adjusting process parameters to achieve a desired thickness of the SiN layer.

12. The method of claim 11, wherein the process parameters include deposition time, etching duration, and nitridation temperature.

13. The method of claim 11, further comprising performing a DHF post-etching process or a H₃PO₄ post-etching process to further refine the profile of the SiN layer.

14. The method of claim 11, wherein the measurement is conducted using a real-time thickness measurement system.

15. The method of claim 11, wherein the profile of the SiN layer is monitored using transmission electron microscopy (TEM).

16. The method of claim 11, wherein the cycle is repeated at least 10 times.

17. The method of claim 11, wherein the cycle is repeated at least 20 times.

18. A semiconductor structure comprising:
a silicon substrate; and
a bottom SiN film formed on the silicon substrate using a cyclic deposition-etching-nitridation process, wherein the bottom SiN film is greater than 150 Å.

19. The semiconductor structure of claim 18, wherein the silicon substrate comprises a plurality of gaps, and the bottom SiN film is formed within each of the gaps.

20. The semiconductor structure of claim 18, further comprising a gate structure formed on the silicon substrate and adjacent to the bottom SiN film.
